(19) United States
(12) Patent Application Publication
(10) Pub. No.: US 2006/0197409 A1
(43) Pub. Date: Sep. 7, 2006

(54) Two-dimensional (2d) array capable of harmonic generation for ultrasound imaging

(75) Inventor: Karl Thiele, Andover, MA (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electonics, N.V., Eindhoven (NL)

(21) Appl. No.: 10/551,321

(22) PCT Filed: Apr. 5, 2004
(86) PCT No.: PCT/IB04/01116

§ 371 Date: Sep. 22, 2005

Related U.S. Application Data
(60) Provisional application No. 60/463,096, filed on Apr. 15, 2003.

(51) Int. Cl. H01L 41/08

(52) U.S. Cl. 310/317; 310/334

(57) ABSTRACT

A two-dimensional (2D) array transducer capable of transmitting ultrasonic energy in tissue at a fundamental frequency and of sufficient power to generate a harmonic of the fundamental frequency. In particular, the invention requires that at least 25% of the array elements are excited to transmit the ultrasonic energy, that the transducer array has a checkerboard pattern, that high voltage electronics are housed in a transducer handle, that transmit and receive beamforming electronics are housed in a transducer handle, that high voltage electronics connected to transmit elements in the transducer and low voltage electronics connected to receive elements in the transducer are housed in the transducer handle, and that elements forming the array are of a single crystal.

The present invention relates to an array transducer for an ultrasonic imaging system. More particularly, the present invention relates to a two-dimensional (2D) array transducer capable of transmitting ultrasonic energy in tissue at a fundamental frequency and of sufficient power to generate a harmonic of the fundamental frequency in the tissue.

Ultrasonic imaging systems are widely used to produce an image of inside a person's body.

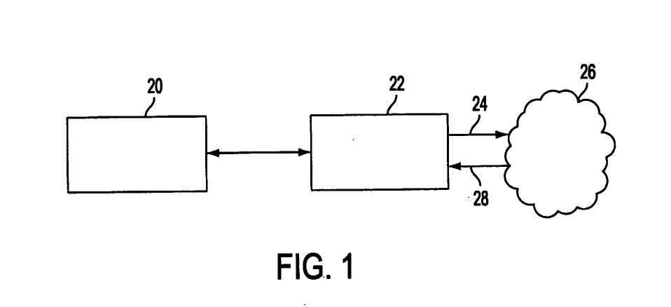

FIG. 1 is a diagram illustrating the general concept of an ultrasonic imaging system. Referring now to FIG. 1, electronics 20 produces control signals for a transducer 22. In accordance with the control signals, transducer 22 transmits ultrasonic energy 24 into tissue 26, such as that in a human body. Ultrasonic energy 24 causes tissue 26 to generate a signal 28 which is detected by transducer 22. Electronics 20 then forms an image in accordance with the detected signals 28.

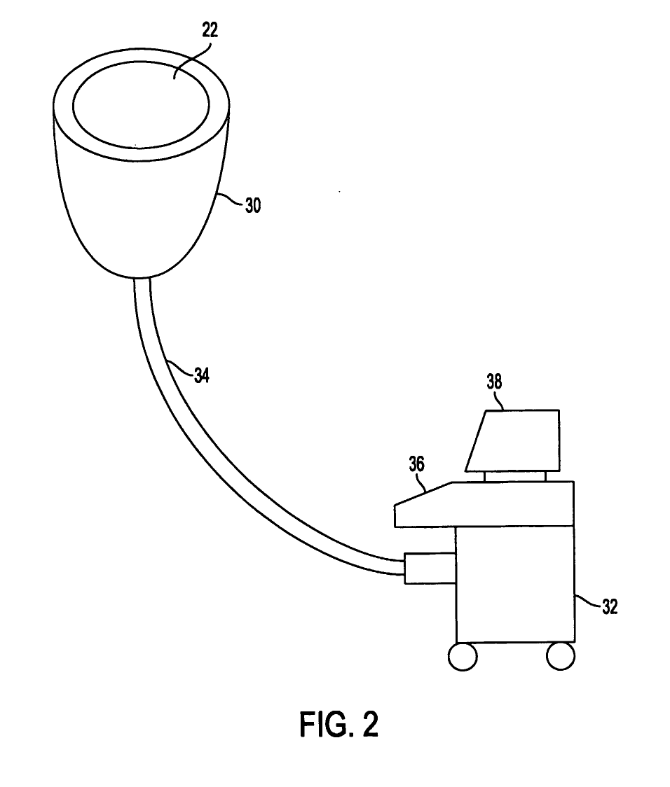

FIG. 2 is a diagram illustrating the physical structure of a typical ultrasonic imaging system. Referring now to FIG. 2, transducer 22 is housed inside a transducer handle 30. Electronics 20 (not shown in FIG. 2, but see FIG. 1), are housed inside an electronics box 32. Transducer 22 is connected to electronics 20 inside electronics box 32 via a cable 34. Electronics 20 inside electronics box 32 is interfaced with a keyboard 36 and provides imaging signals to a display 38.

Referring again to FIG. 1, in a typical manner of performing ultrasound imaging, ultrasound energy 24 transmitted by transducer 22 is at the same frequency as signal 28 detected by transducer 22. For example, ultrasound energy 24 and signal 28 might both be at 2.5 MHz. With this type of ultrasound imaging, a two-dimensional (2D) sparse array transducer is typically used as transducer 22.

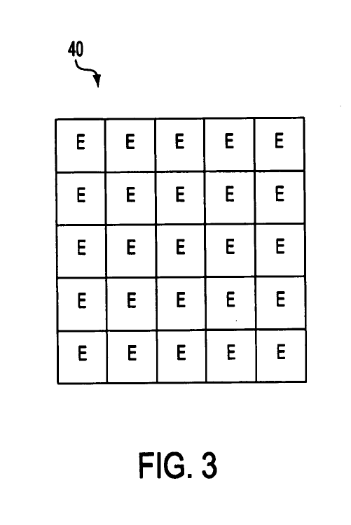

For example, FIG. 3 is a diagram illustrating a 2D array transducer 40. Referring now to FIG. 3, 2D array transducer 40 includes a plurality of piezoelectric elements (E) arranged in a matrix format with rows and columns. Although FIG. 2 shows only twenty-five piezoelectric elements (E), an actual 2D array transducer would typically have many more piezoelectric elements (E). For example, a typical 2D array transducer might be a 50×50 array, thereby constituting a total of two-thousand-five-hundred piezoelectric elements (E).

Generally, if each of the twenty-five-hundred piezoelectric element (E) were utilized, an individual wire for each piezoelectric element (E) to electronic 20 would be required to appropriately control the piezoelectric elements (E). As a result, an extremely large cable 34 of twenty-five-hundred wires would be required to connect electronics 20 to piezoelectric elements (E). Such a cable would be too large for many practical applications.

Therefore, to reduce the number of wires running through cable 34, only a small number of the total number of piezoelectric elements (E) in a 2D array transducer are actually wired for use. For example, in conventional ultrasound imaging systems, only 10% or less of the total number of piezoelectric elements (E) are wired for use. As a numerical example, a 2D array transducer with a total of two-thousand-five-hundred piezoelectric elements (E) would typically have less then two-hundred-fifty of the piezoelectric elements (E) wired for use. Of these, some would be used to transmit ultrasonic energy and others would be used to detect a signal generated in tissue. Since only 10% or less of the total number of piezoelectric elements (E) are wired, such transducers are referred to as “sparse” array transducers.

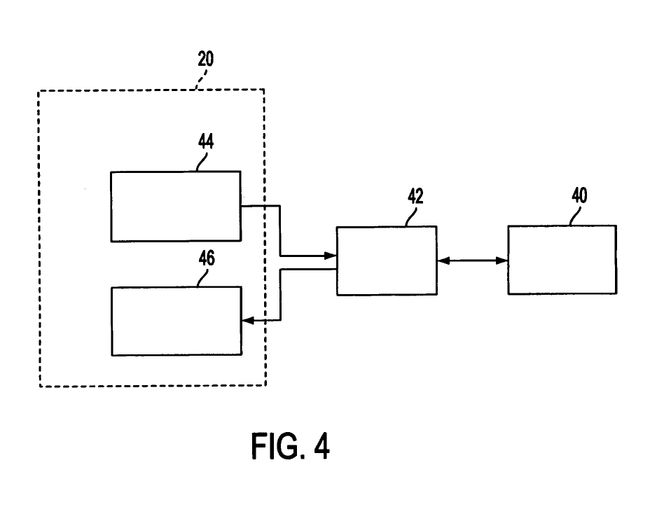

In some systems, including those using sparse array transducers, a transmit/receive (T/R) switch is used to allow the same piezoelectric elements (E) to transmit and receive. For example, FIG. 4 is a diagram illustrating the use of a transmit/receive (T/R) switch 42 connected to 2D array transducer 40. Referring now to FIG. 4, a transmit beamformer 44 generates excitation signals. When transmitting, T/R switch 42 connects transmit beamformer 44 to piezoelectric elements (E) in array transducer 40, so that the piezoelectric elements (E) transmit ultrasonic energy in accordance with the excitation signals.

Thereafter, T/R switch 42 disconnects transmit beamformer 44 from the piezoelectric elements (E) and instead connects receive beamformer 46 to these same piezoelectric elements (E). Receive beamformer 46 then processes the signal received by the piezoelectric elements (E). Such use of a T/R switch to connect a transmit beamformer and a receive beamformer to the same piezoelectric element is well-known in the art.

Using a T/R switch to allow the same piezoelectric elements (E) of a 2D array transducer to be used to transmit and receive has many advantages. One advantage is that the total number of wired piezoelectric elements being can be relatively small. The total number of wired piezoelectric elements can further be reduced by using a spared array transducer. As a result of such techniques, the total wire count in cable 34 can be reduced.

A significant advantage of a 2D array transducer, such as a sparse array transducer, is that it can scan in three-dimensions. Such operation is highly desirable in many situations.

For the above reasons, sparse array transducers are widely used in ultrasound imaging systems, especially in systems where the transmitted ultrasonic energy is at the same frequency as the received signal generated in the tissue, such as in FIG. 1 where transmitted ultrasonic energy 24 is at the same frequency as the received signal 28.

However, there is a type of ultrasound imaging which employs “native harmonics.” Referring now to FIG. 1, with native harmonics, the transmitted ultrasonic energy 24 is at a fundamental frequency and is of sufficient power to generate a harmonic of the fundamental frequency in the tissue. This harmonic is the detected signal 28 in FIG. 1.

Unfortunately, since a sparse array transducer uses a relatively small amount of the total number of piezoelectric elements (E) forming the transducer, a sparse array transducer cannot generate ultrasonic energy of sufficient power to generate the harmonic. Therefore, sparse array transducers are not used for native harmonics ultrasonic imaging.

In theory, a larger number of piezoelectric elements (E) of an array transducer could be wired for transmitting ultrasonic energy, to hopefully produce sufficient power to generate the harmonic. However, such operation would require too many wires to run through cable 34 in FIG. 2, thereby making such a system impractical. Moreover, conventional electronics typically used with array transducers would not allow sufficient power to be generated inside the small area of handle 30 in FIG. 2, even if more piezoelectric elements (E) were used. For these reasons, 2D array transducers, including sparse array transducers, are not used with native harmonics ultrasonic imaging.

Instead, one-dimensional (ID) array transducers are used to transmit ultrasonic energy with native harmonics ultrasonic imaging, because 1D array transducers can produce ultrasonic energy of sufficient power to generate a harmonic in tissue. However, 1D array transducers are undesirable in that they can only scan in two-dimensions. Such operation can be compared to a 2D array transducer, which can scan in three-dimensions.

Accordingly, it is an object of the present invention to provide a 2D transducer array for use with native harmonic ultrasonic imaging.

Additional objects and advantages of the invention will be set forth in part in the description which follows, and, in part, will be obvious from the description, or may be learned by practice of the invention.

Objects of the present invention are achieved by providing 2D array transducer capable of transmitting ultrasonic energy in tissue at a fundamental frequency and of sufficient power to generate a harmonic of the fundamental frequency in the tissue.

Objects of the present invention are also achieved by providing a two-dimensional (2D) array transducer comprising a total number of piezoelectric elements of which at least 25% are excited to transmit ultrasonic energy in tissue at a fundamental frequency and of sufficient power to generate a harmonic of the fundamental frequency in the tissue.

In addition, objects of the present invention are achieved by providing an apparatus including (a) a transducer handle positionable near tissue, the handle external to ultrasound processing equipment producing control signals for ultrasound imaging; (b) at least some transmit beamforming electronics housed in the handle and generating excitation signals in accordance with the control signals; and (c) a two-dimensional (2D) array transducer housed in the handle and, in accordance with the excitations signals, transmitting ultrasonic energy in tissue at a fundamental frequency and of sufficient power to generate a harmonic of the fundamental frequency in the tissue.

Moreover, objects of the present invention are achieved by providing an apparatus including (a) electronic processing equipment producing control signals for ultrasound imaging; (b) a handle external to the electronic processing equipment and positionable near tissue; (c) at least some transmit beamforming electronics housed in the handle; (d) a communication channel connecting the electronic processing equipment to the transmit beamforming electronics in the handle so that the transmit beamforming electronics generates excitation signals in accordance with the control signals produced by the electronic processing equipment; and (e) a two-dimensional (2D) array transducer housed in the handle and, in accordance with the excitation signals, transmitting ultrasonic energy in tissue near which the handle is positioned at a fundamental frequency and of sufficient power to generate a harmonic of the fundamental frequency in the tissue.

Objects of the present invention are further achieved by providing an array transducer having a checkerboard pattern formed by a plurality of elements, each element used to either transmit ultrasonic energy at a fundamental frequency or receive a signal generated in tissue by the transmitted ultrasonic energy.

Objects of the present invention are also achieved by providing an array transducer having a checkerboard pattern formed by a total number of elements, at least 25% of the total number of elements used to transmit ultrasonic energy at a fundamental frequency, and a plurality of the elements used to receive a signal generated in tissue by the transmitted ultrasonic energy.

Further, objects of the present invention are achieved by providing an array transducer having a checkerboard pattern formed by a total number of elements, at least 25% of the total number of elements connected to high-voltage electronics to transmit ultrasonic energy at a fundamental frequency, and a plurality of the elements connected to low-voltage electronics to receive a signal generated in tissue by the transmitted ultrasonic energy.

In addition, objects of the present invention are achieved by providing an array transducer having a checkerboard pattern formed by a plurality of elements in an alternating transmit-receive checkerboard pattern, where transmitting elements transmit ultrasonic energy at a fundamental frequency and receiving elements receive a signal generated in tissue by the transmitted ultrasonic energy.

Moreover, objects of the present invention are achieved by providing a 2D array transducer for which (a) at least 25% of the array elements are excited to transmit the ultrasonic energy, (b) the transducer array has a checkerboard pattern, (c) high voltage electronics are housed in a transducer handle, (d) transmit and receive beamforming electronics are housed in the transducer handle, (e) high voltage electronics connected to transmit elements in the transducer and low voltage electronics connected to receive elements in the transducer are housed in the transducer handle, (f) a high impedance backing is provided for piezoelectric elements forming the transducer, (g) elements forming the array are of a single crystal and (h) ultrasonic energy is provided with a bandwidth which is at least 60% of the fundamental frequency, and/or (i) ultrasonic energy is transmitted with sufficient power so that a second harmonic in the tissue is less than to 15 dB from the power level of the fundamental in the tissue.

These and other objects and advantages of the invention will become apparent and more readily appreciated from the following description of the preferred embodiments, taken in conjunction with the accompanying drawings of which:

FIG. 1 (prior art) is a diagram illustrating the general concept of an ultrasonic imaging system.

FIG. 2 (prior art) is a diagram illustrating the physical structure of a typical ultrasonic imaging system.

FIG. 3 (prior art) is a diagram illustrating a 2D array transducer.

FIG. 4 (prior art) is a diagram illustrating the use of a transmit/receive (T/R) switch with a 2D array transducer.

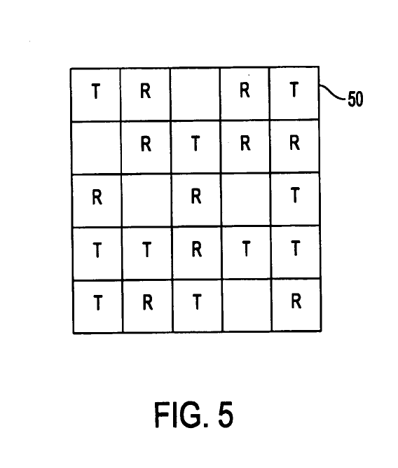

FIG. 5 is a diagram illustrating a 2D array transducer, according to an embodiment of the present invention.

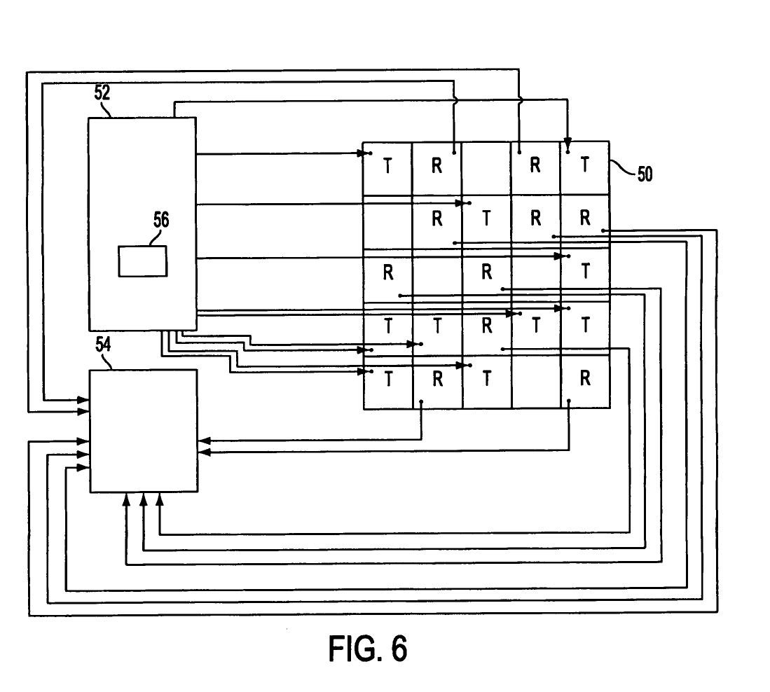

FIG. 6 is a diagram illustrating transmitting piezoelectric elements of a 2D array transducer being connected to high voltage electronics, whereas receiving piezoelectric elements are connected to low voltage electronics, according to an embodiment of the present invention.

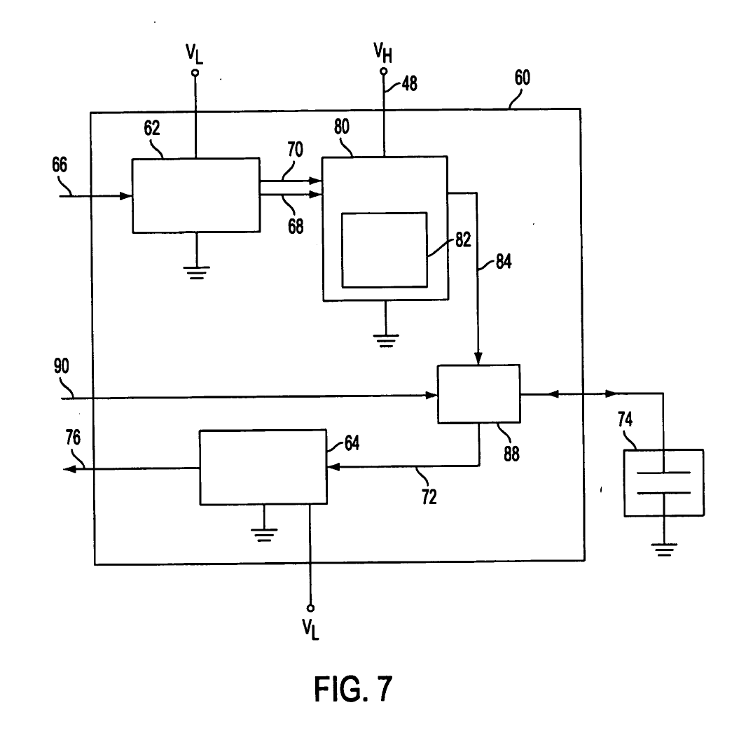

FIG. 7, is a diagram illustrating low voltage and high voltage electronics used with a 2D transducer array, according to an embodiment of the present invention.

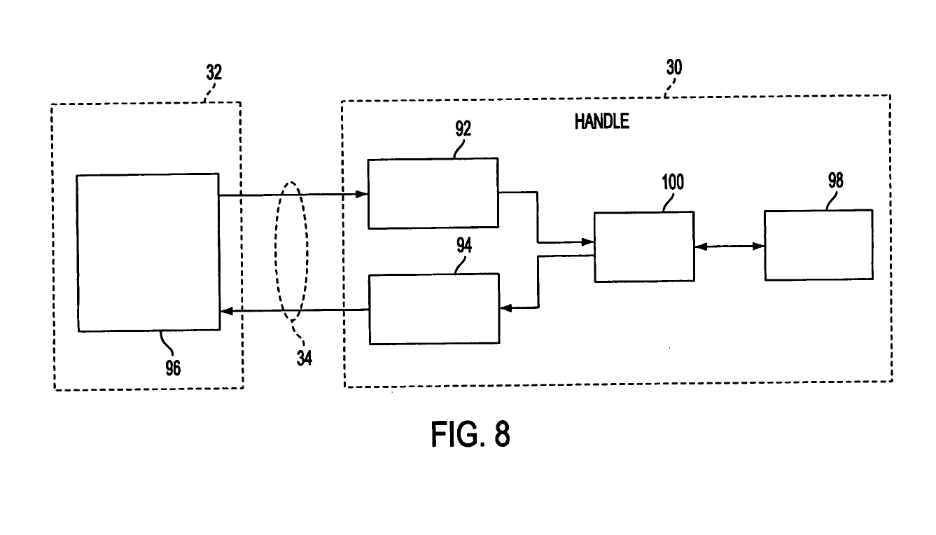

FIG. 8 is a diagram illustrating a transmit beamformer and a receive beamformer for a 2D array transducer and housed inside a transducer handle, according to an embodiment of the present invention.

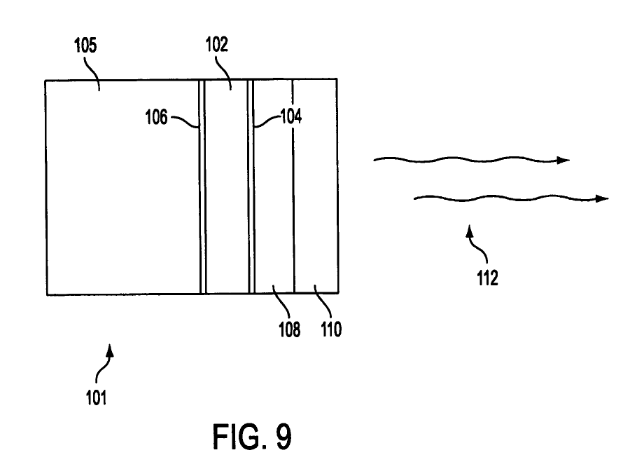

FIG. 9 is a diagram illustrating a high impedance backing for piezoelectric elements of a 2D array transducer, according to an embodiment of the present invention.

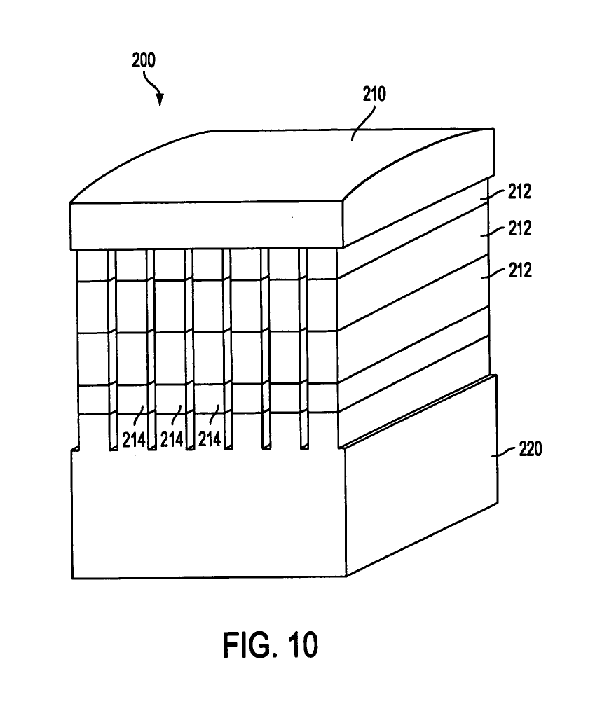

FIG. 10 is a diagram illustrating a single crystal transducer for use in a 2D array transducer, according to an embodiment of the present invention.

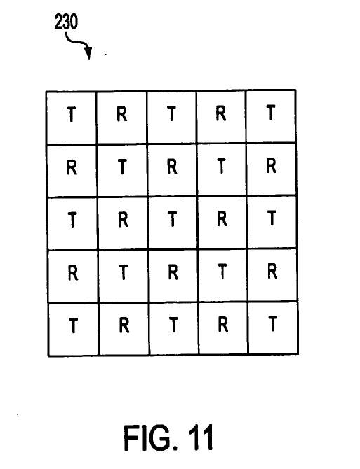

FIG. 11 is a diagram illustrating a 2D array transducer having a checkerboard pattern, according to embodiments of the present invention.

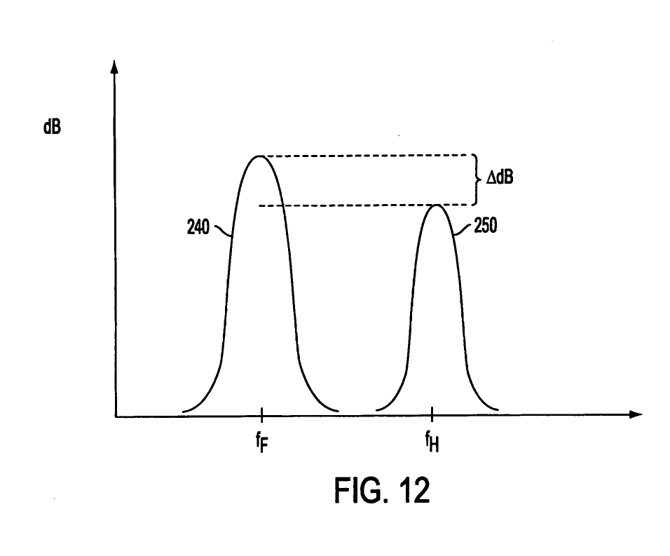

FIG. 12 is a diagram illustrating the power level of ultrasonic energy at a fundamental and at a second harmonic, according to an embodiment of the present invention.

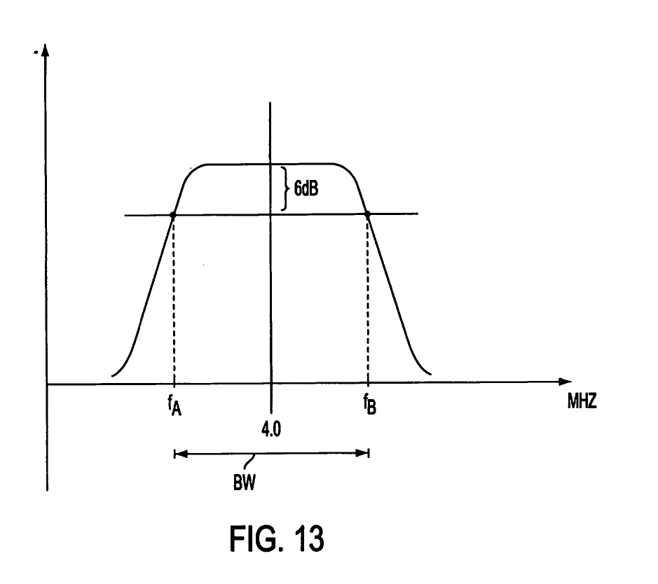

FIG. 13 is a diagram showing the bandwidth of transmitted ultrasound energy, according to an embodiment of the present invention.

Reference will now be made in detail to the present preferred embodiments of the present invention, examples of which are illustrated in the accompanying drawings, wherein like reference numerals refer to like elements throughout.

FIG. 5 is a diagram illustrating a 2D array transducer 50, according to an embodiment of the present invention. Referring now to FIG. 5, at least 25% of the total number of piezoelectric elements in 2D array transducer 50 are excited to transmit ultrasonic energy. Thus, 25% to 100% of the piezoelectric elements should be used to transmit. For example, in FIG. 5, piezoelectric elements used to transmit are labeled “T,” and piezoelectric elements used to receive are labeled “R.” 2D array transducer 50 has a total of twenty-five piezoelectric elements, of which ten are used to transmit. Thus, more than 25% of the piezoelectric elements are used to transmit. Although FIG. 5 shows 2D array transducer 50 as having only twenty-five piezoelectric elements, an actual 2D array transducer would likely have many more piezoelectric elements. For example, a typical 2D array transducer might be a 50×50 array, thereby constituting a total of two-thousand-five-hundred piezoelectric elements (E). Thus, the present invention is not limited to an array transducer having any particular number of piezoelectric elements. Moreover, FIG. 5 shows all the rows in the array being used. However, in practice, it is likely that some of the rows would not be used. For example, in a typical, practical embodiment, the outside row might not be used.

By using more piezoelectric elements to transmit than a typical sparse array transducer, 2D array transducer 50 can be made to transmit ultrasonic energy of sufficient power to generate harmonics in tissue.

In an example embodiment of the present invention, the transmitting piezoelectric elements would typically be connected to high voltage electronics.

For example, FIG. 6 is a diagram illustrating piezoelectric elements (T) used to transmit being connected to high voltage electronics 52, whereas piezoelectric elements (R) used to receive are connected to low voltage electronics 54, according to an embodiment of the present invention. High voltage electronics 52 might use a field-effect transistor (FET) 56 to drive piezoelectric elements (T) used to transmit, to thereby generate sufficient power. Here, the term “high voltage” indicates a voltage of greater than or equal to 10V. Typically, the high voltage would be in a range of 50V to 150V to generate ultrasonic energy with sufficient power to generate harmonics. High voltage electronics 52 and low voltage electronics 54 would typically be considered to be part of transmit or receive beamforming electronics. FIG. 6 is only intended as a conceptual diagram, and the actually wiring would typically look significantly different than that shown in the figure.

As a more detailed example, FIG. 7, is a diagram illustrating low voltage and high voltage electronics used with a 2D transducer array, according to an embodiment of the present invention. Referring now to FIG. 7, transducer circuitry 60 includes at least one of a low-voltage transmit circuit 62 and a low-voltage receive circuit 64. Low-voltage transmit circuit 62 and low-voltage receive circuit 64 are shown as being connected between a supply voltage V_{L}, typically on the order of approximately 5 volts, and ground. Low-voltage transmit circuit 62 receives one or more control signals, for example, from an electronics box of an ultrasound imagining system or other circuitry (not shown) via line 66, and outputs one or more low-voltage transmit signals via lines 68 and 70. Low-voltage receive circuit 64 processes signals, input via line 72, that represent ultrasound energy received by transducer element 74, and outputs the processed signals, for example, to other circuitry or to the electronics box of the ultrasound imaging system, via line 76.

Transducer circuitry 60 also includes a high-voltage circuit 80, connected between a high supply voltage V_{H}, typically in the range of approximately 20-100 volts, and ground. High-voltage circuit 80 includes a high-voltage FET 82 to drive transducer element 74 via line 84, based on signals received from low-voltage transmit circuit 62 via lines 68 and 70.

Transducer circuitry 60 may optionally include a transmit/receive (T/R) switch 88 operated by a control signal received on line 90. T/R switch 88 allows the ultrasound imaging system to use one ultrasound transducer element 74 for both transmitting and receiving ultrasound energy. Alternatively, the ultrasound imaging system may employ transducer elements that are dedicated to either transmitting or receiving ultrasound energy. For example, high-voltage circuit 80 may be connected directly to one ultrasound transducer element via line 84, and another ultrasound transducer element (not shown in FIG. 7) may be connected directly to low-voltage receive circuit 64 via line 72.

According to an embodiment of the present invention, at least one of low-voltage transmit circuit 62 and low voltage receive circuit 64, and high-voltage circuit 80, are monolithically fabricated on a single substrate, preferably using conventional low-voltage component fabrication processes, to form transducer circuitry 60.

Moreover, transducer circuitry 60 can be housed inside handle 30 (see FIG. 2), to thereby provide high power on transmit, but reducing the wire count in cable 34 (see FIG. 2).

Such use of high and low voltage electronics, and the housing of such electronics inside the transducer handle, is described in detail in U.S. patent application Ser. No. 09/272,946, filed Mar. 19, 1999, inventor Bernard J. Savord, which is incorporated herein by reference. FIG. 8 is a diagram illustrating transmit beamformer 92 and receive beamformer 94 housed inside handle 30, to thereby produce sufficient power on transmit and to also reduce wire count in cable 34, according to an embodiment of the present invention. In such an embodiment, some transmit and/or receive beamforming electronics might also be performed by electronics 96 inside electronics box 32. Thus, electronics 96 and transmit beamformer 92 operate together to provide appropriate beamforming excitation signals to cause 2D array transducer 98 to transmit ultrasonic energy of sufficient power to generate harmonics in tissue. Similarly, electronics 96 and receive beamformer 94 operate together to process the harmonic detected by 2D array transducer 98. A T/R switch 100 can be used if the same piezoelectric elements of 2D array transducer 98 are used for transmitting and receiving.

The use of at least some transmit and receive beamforming electronics in the handle is described in detail in U.S. Pat. No. 5,997,479, Savord et. al, and U.S. Pat. No. 6,013,032, Savord et. al, which are incorporated herein by reference.

To improve the power efficiency in transmitting ultrasonic energy from a 2D transducer array, the piezoelectric elements of the 2D array transducer can be provided with a high impedance backing.

For example, FIG. 9 is a diagram illustrating a high impedance backing for piezoelectric elements of a 2D array transducer 101, according to an embodiment of the present invention. Referring now to FIG. 9, an array 102 of active elements transmits and receives acoustic beams formed by, for example, the switching of each element in a phased array format. The elements are preferably formed of piezoelectric crystals and there may be a single one or a plurality of electrically-independent active elements in array 102. A top electrode layer 104 overlying and a bottom electrode layer 106 underlying each active element enables the element to be individually and electrically addressed. Base 105 of acoustic backing material provides structural support for array 102 of transducer elements and their associated electrodes 104, 106. Backing materials for use in base 105 are formed, preferably, as a composite of a fiber structure and a matrix material for structural strength and rigidity.

Gaps or kerfs cut between individual active elements achieve acoustic isolation between them. An acoustic matching layer 108 may be included to provide acoustic impedance transition between array 102 and an acoustic lens 110. The desired emission 112 of transducer 101 is considered as emanating from the “forward” or foremost side of transducer 101, with base 105 and ancillary components attached to base 105 (such as a housing and the like, which are being omitted for clarity) being generally considered as located at the “rear” or backside of transducer 101. The rear surface of array 102 is coupled to electrode layer 106.

Array 102 is subject to unwanted acoustical emissions that emanate from the backside of array 102 and into base 105. Appropriate backing materials for use in base 105 are formed as a composite of a preform and a matrix material for improved acoustical attenuation of such unwanted emissions. An embodiment of the composite includes a preform that is filled with a suitable matrix such as plastic, resin, or other solutions to form the composite. The resulting composite may be formed via materials process techniques as a continuous ribbon, cylinder, etc., of backing material (e.g., in a bulk material form) or as one or more composite structure via materials forming techniques such as pultrusion, molding (e.g., injection molding or compression molding), and/or hardening by thermosetting, chemical reaction, or curing. A composite structure may thus be provided in a preferred form factor, or be machined to the desired shape, so as to be easily integrated into transducer 101.

The design and use of a high impedance backing for transducer elements is described in detail in U.S. Pat. No. 5,648,941, King, which is incorporated herein by reference.

Further, to improve transmit efficiency, a 2D array transducer can be formed of piezoelectric elements of a single crystal.

For example, FIG. 10 is a diagram illustrating a single crystal transducer 200, according to an embodiment of the present invention. Referring now to FIG. 10, transducer 200 comprises single crystal element slivers 214 which also include multiple matching layers. As shown in FIG. 10, transducer 200 comprises a backing 220 and an acoustic lens 210. Interposed between slivers 214 and acoustic lens 210 are, in this example, three matching layers 212. The use of three such matching layers 212 in combination with single crystal slivers 214 render significant advantages.

The design and use of a single crystal transducer is described in detail in U.S. Pat. No. 6,425,869, issued Jul. 30, 2002, Jie Chen, which is incorporated herein by reference.

Further, a transducer array, according to embodiments of the present invention, can have a checkerboard pattern of transmitting and receiving elements.

For example, FIG. 11 is a diagram illustrating a 2D array transducer 230 having a checkerboard pattern, according to an embodiment of the present invention. Referring now to FIG. 11, elements which transmit are labeled as “T,” and elements that receive are labeled as “R.” A checkerboard pattern is defined as having alternatively positioned transmit (T) and receive (R) elements, so that no two adjacent elements have an unused element between them, as illustrated, for example, in FIG. 10. 50% of the used elements might be used to transmit, and the other 50% of the used elements might be used to receive. However, it is not necessary to have a 50/50 ratio. Instead, in a typical embodiment, at least 25% of the total number of elements in the transducer would be used to transmit, so that sufficient transmit energy can be obtained.

Moreover, a checkerboard pattern does not require that all of the total number of elements in the transducer be used. For example, various elements in the outer rows, or the boundaries, might not typically be used.

Although FIG. 11 shows only twenty-five elements, an actual 2D array transducer would typically have many more elements. For example, a typical 2D array transducer might be a 50×50 array, thereby constituting a total of two-thousand-five-hundred elements. Thus, the present invention, and a checkerboard pattern, is not limited to having any particular number of elements.

As described above, in a typical embodiment where a 2D array transducer with a checkerboard pattern is used in native harmonics ultrasonic imaging, the transmitting elements would typically be connected to high-voltage electronics to transmit ultrasonic energy at a fundamental frequency and of sufficient power to generate a harmonic in tissue. The receiving elements would be connected to low-voltage electronics to receive and process the generated harmonics. As described above, the high-voltage and low-voltage electronics can be housed inside the array transducer handle.

According to the above embodiments of the present invention, a 2D array transducer transmits ultrasonic energy in tissue at a fundamental frequency and of sufficient power to generate a harmonic of the fundamental frequency in the tissue. Preferably, the transmitted ultrasonic energy is of sufficient power so that a second harmonic generated in the tissue has a maximum power level of less than 15 dB from the maximum power level of the fundamental frequency in the tissue.

For example, FIG. 12 is a diagram illustrating a curve 240 showing the power level of the ultrasonic energy at the fundamental f_{F} in tissue, and a curve 250 showing the power level of the second harmonic f_{H} in the tissue, according to an embodiment of the present invention. Referring now to FIG. 12, the difference of the maximum power level of the fundamental and the maximum power level of the second harmonic is ΔdB. Preferably, ΔdB is less than or equal to 15 dB. This difference in power can be obtained by causing the transmitted ultrasonic energy to have sufficient power level to produce such a power level difference, in accordance with the above described embodiments of the present invention.

Moreover, preferably, the transmitted ultrasound energy has a waveform with a bandwidth BW greater than or equal to 60% of the fundamental frequency.

For example, FIG. 13 is a diagram showing the bandwidth of a transmitted ultrasound energy, according to an embodiment of the present invention. Referring now to FIG. 13, in this example, the fundamental frequency is 4.0 MHz. Frequency f_{A} is lower than the fundamental frequency and is at a point 6 dB from the maximum power level at the fundamental frequency. Frequency f_{B} is higher than the fundamental frequency and is at a point 6 dB from the maximum power level at the fundamental frequency. The bandwidth BW equals (f_{B}-f_{A}). Preferably, the bandwidth BW should be greater than or equal to 60% of the fundamental frequency f_{F}. Therefore, in the example of FIG. 13, the bandwidth BW should be greater than or equal to 2.4 MHz, which is 60% of the fundamental frequency 4.0 MHz.

The specific frequencies in FIG. 13 are only intended as an example, and the present invention is not limited to any specific frequencies.

According to the above embodiments of the present invention, a two-dimensional (2D) array transducer is capable of transmitting ultrasonic energy in tissue at a fundamental frequency and of sufficient power to generate a harmonic of the fundamental frequency in tissue. In various embodiments of the present invention, (a) at least 25% of the array elements are excited to transmit the ultrasonic energy, (b) the transducer array has a checkerboard pattern, (c) high voltage electronics are housed in a transducer handle, (d) transmit and receive beamforming electronics are housed in the transducer handle, (e) high voltage electronics connected to transmit elements in the transducer and low voltage electronics connected to receive elements in the transducer are housed in the transducer handle, (f) a high impedance backing is provided for piezoelectric elements forming the transducer, (g) elements forming the array are of a single crystal and (h) ultrasonic energy is provided with a bandwidth which is at least 60% of the fundamental frequency, and (i) ultrasonic energy is transmitted with sufficient power so that a second harmonic in the tissue is less than to 15 dB from the power level of the fundamental in the tissue. The present invention is not limited to (a) to (i) being used individually or together. Instead, all possible combinations of (a) to (i) are encompassed by the present invention.

The above embodiments of the present invention relate to an ultrasonic imaging system where an array transducer is housed in a handle, and connected to electronics inside an electronics box by a cable, as disclosed, for example, in FIG. 2. Therefore, the cable is a communication channel connecting the transducer to the electronics inside the electronics box. However, the present invention is not limited to such a communication channel being a “cable” and can be any communication channel which allows for the appropriate communication between the transducer and the electronics. For example, a wireless communication channel could be used to connect the transducer to the electronics inside the electronics box. An appropriate communication channel could also be a network such as a local area network (LAN), a wide area network (WAN), an optical communication network, a wireless communication network, an electrical communication network or any combination of these. For example, the communication channel could be the Internet, where an array transducer is connected to appropriate electronics over the Internet.

Various embodiments of the present invention relate to a transducer being housed in a “handle,” such as handle 30 in FIG. 2. Here, the term “handle” indicates an enclosure that houses a transducer, where the enclosure is designed to be held and then moved in position near tissue to be imaged. Typically, the “handle” would be held by a person, such as a doctor, nurse, technician, or otherwise qualified person, to obtain an appropriate image of the tissue. A handle is not intended to being limited to any particular shape.

Moreover, the present invention is not limited to an ultrasonic imaging system where the transducer is housed in a handle and connected to electronics inside an electronics box, as disclosed in FIG. 2. Instead, for example, the present invention is applicable to embodiments where the transducer and all the electronics are housed in the same housing. For example, the present invention is applicable to portable or non-portable ultrasonic imaging systems where the entire system is housed within a single enclosure. Moreover, the present invention is not limited to any particular components being housed in any particular enclosure. Further, an electronics “box,” such as that shown in FIG. 2, is not limited to being a square or rectangular “box” shape, and can have any shape sufficient to house the electronics.

According to the above embodiments of the present invention, a 2D array transducer includes piezoelectric elements. However, the present invention is not limited to the elements being “piezoelectric” elements. Instead, an element can be made of a different material as long as it provides the desired effect for transmitting ultrasonic energy.

Although a few preferred embodiments of the present invention have been shown and described, it would be appreciated by those skilled in the art that changes may be made in these embodiments without departing from the principles and spirit of the invention, the scope of which is defined in the claims and their equivalents.

1. An apparatus comprising:
a two-dimensional (2D) array transducer transmitting ultrasonic energy in tissue at a fundamental frequency and of sufficient power to generate a harmonic of the fundamental frequency in the tissue.

2. An apparatus as in claim 1, wherein the array transducer includes a total number of elements of which at least 25% are excited to transmit the ultrasonic energy.

3. An apparatus as in claim 1, further comprising:
transmit beamforming electronics including a high voltage circuit driving the array transducer to transmit the ultrasonic energy.

4. An apparatus as in claim 1, further comprising:
a high voltage field effect transistor (FET) driving the array transducer to transmit the ultrasonic energy.

5. An apparatus as in claim 1, further comprising:
means for driving the array transducer with a high voltage to transmit the ultrasonic energy.

6. An apparatus as in claim 1, wherein the array transducer includes a plurality of piezoelectric elements forming the array transducer, the apparatus further comprising:
a high impedance backing for the piezoelectric elements.

7. An apparatus as in claim 1, wherein the array transducer includes a plurality of piezoelectric elements forming the array transducer, the apparatus further comprising:
means for providing a high impedance backing for the piezoelectric elements.

8. An apparatus as in claim 1, wherein the array transducer is constructed of materials comprising a single crystal.

9. An apparatus as in claim 1, wherein the array transducer is constructed of a plurality of piezoelectric elements of a single crystal.

10. An apparatus as in claim 1, wherein the array transducer transmits the ultrasound energy with a waveform having a bandwidth BW greater than or equal to 60% of the fundamental frequency, where BW=(f_{B}-f_{A}), f_{B} is a higher frequency than the fundamental frequency at a power level 6 dB lower than at the fundamental frequency, f_{A} is a lower frequency than the fundamental frequency at a power level 6 dB lower than the fundamental frequency.

11. An apparatus as in claim 1, wherein the array transducer transmits the ultrasonic energy at a sufficient power to generate a second harmonic in the tissue having a maximum power level of less than 15 dB from the maximum power level of the fundamental frequency in the tissue.

12. An apparatus as in claim 1, wherein the array transducer has a checkerboard pattern formed by a plurality of elements, each element used for either transmit or receive.

13. An apparatus as in claim 1, wherein the array transducer has a checkerboard pattern formed by a total number of elements, at least 25% of the total number of elements being used to transmit and a plurality of the elements used to receive.

14. An apparatus as in claim 1, wherein the array transducer has a checkerboard pattern formed by a total number of elements, at least 25% of the total number of elements connected to high-voltage electronics to transmit the ultrasonic energy, and a plurality of the elements connected to low-voltage electronics to receive the generated harmonic.

15. An apparatus as in claim 1, wherein the array transducer is formed by a plurality of elements in an alternating transmit-receive checkerboard pattern.

16. An apparatus as in claim 1, further comprising:
a low-voltage circuit; and
a high-voltage circuit driving the array transducer to transmit the ultrasonic energy, the high voltage circuit including a high-voltage FET, the low-voltage circuit and the high-voltage circuit being monolithically formed on a single substrate.

17. An apparatus as in claim 1, further comprising:
a low-voltage circuit; and
a high-voltage circuit driving the array transducer to transmit the ultrasonic energy, the low-voltage circuit and the high-voltage circuit being formed on a single substrate.

18. An apparatus as in claim 1, further comprising:
means for providing a low-voltage circuit and a high-voltage circuit both formed on the same single substrate, the high-voltage circuit for driving the array transducer to transmit the ultrasonic energy.

19. An apparatus comprising:
a two-dimensional (2D) array transducer comprising a total number of piezoelectric elements of which at least 25% are excited to transmit ultrasonic energy in tissue at a fundamental frequency and of sufficient power to generate a harmonic of the fundamental frequency in the tissue.

20. An apparatus as in claim 19, further comprising:
a high voltage field effect transistor (FET) driving the excited piezoelectric elements to transmit the ultrasonic energy.

21. An apparatus as in claim 19, further comprising:
means for driving the excited piezoelectric elements with a high voltage to transmit the ultrasonic energy.

22. An apparatus as in claim 19, further comprising:
a high impedance backing for the piezoelectric elements.

23. An apparatus as in claim 19, further comprising:
means for providing a high impedance backing for the piezoelectric elements.

24. An apparatus as in claim 20, further comprising:
a high impedance backing for the piezoelectric elements.

25. An apparatus as in claim 19, wherein the piezoelectric elements are of a single crystal.

26. An apparatus as in claim 20, wherein the piezoelectric elements are of a single crystal.

27. An apparatus as in claim 22, wherein the piezoelectric elements are of a single crystal.

28. An apparatus as in claim 19, wherein the array transducer transmits the ultrasound energy with a waveform having a bandwidth BW greater than or equal to 60% of the fundamental frequency, where BW=(f_{B}-f_{A}), f_{B} is a higher frequency than the fundamental frequency at a power level 6 dB lower than at the fundamental frequency, f_{A} is a lower frequency than the fundamental frequency at a power level 6 dB lower than the fundamental frequency.

29. An apparatus as in claim 19, wherein the array transducer transmits the ultrasonic energy at a sufficient power to generate a second harmonic in the tissue having a maximum power level of less than 15 dB from the maximum power level of the fundamental frequency in the tissue.

30. An apparatus as in claim 19, wherein the piezoelectric elements are in a checkerboard pattern, each piezoelectric element used for either transmit or receive.

31. An apparatus as in claim 19, wherein the excited piezoelectric elements are connected to high-voltage electronics to transmit the ultrasonic energy, and a plurality of the remaining piezoelectric elements are connected to low-voltage electronics to receive the generated harmonic.

32. An apparatus as in claim 19, wherein the piezoelectric elements are arranged in an alternating transmit-receive checkerboard pattern.

33. An apparatus as in claim 19, further comprising:
a low-voltage circuit; and
a high-voltage circuit driving the excited piezoelectric elements to transmit the ultrasonic energy, the low-voltage circuit and the high-voltage circuit being formed on a single substrate.

34. An apparatus as in claim 19, further comprising:means for providing a low-voltage circuit and a high-voltage circuit both formed on the same single substrate, the high-voltage circuit for driving the excited piezoelectric elements to transmit the ultrasonic energy.

35. An apparatus comprising:
a transducer handle positionable near tissue, the handle external to ultrasound processing equipment producing control signals for ultrasound imaging;
at least some transmit beamforming electronics housed in the handle and generating excitation signals in accordance with the control signals; and
a two-dimensional (2D) array transducer housed in the handle and, in accordance with the excitations signals, transmitting ultrasonic energy in tissue at a fundamental frequency and of sufficient power to generate a harmonic of the fundamental frequency in the tissue.

36. An apparatus as in claim 35, wherein the array transducer includes a total number of elements of which at least 25% are excited to transmit the ultrasonic energy.

37. An apparatus as in claim 35, further comprising:
a high voltage circuit driving the array transducer to transmit the ultrasonic energy and housed in the handle.

38. An apparatus as in claim 35, further comprising:
a high voltage field effect transistor (FET) driving the array transducer to transmit the ultrasonic energy and housed in the handle.

39. An apparatus as in claim 35, further comprising:
means for driving the array transducer with a high voltage to transmit the ultrasonic energy, said means being housed in the handle.

40. An apparatus as in claim 35, wherein the array transducer includes a plurality of piezoelectric elements forming the array transducer, the apparatus further comprising:
a high impedance backing for the piezoelectric elements and housed in the handle.

41. An apparatus as in claim 35, wherein the array transducer includes a plurality of piezoelectric elements forming the array transducer, the apparatus further comprising:
means for providing a high impedance backing for the piezoelectric elements, said means being housed in the handle.

42. An apparatus as in claim 35, wherein the array transducer is constructed of materials comprising a single crystal.

43. An apparatus as in claim 35, wherein the array transducer is constructed of a plurality of piezoelectric elements of a single crystal.

44. An apparatus as in claim 35, wherein the array transducer transmits the ultrasound energy with a waveform having a bandwidth BW greater than or equal to 60% of the fundamental frequency, where BW=(f_{B}-f_{A}), f_{B} is a higher frequency than the fundamental frequency at a power level 6 dB lower than at the fundamental frequency, f_{A} is a lower frequency than the fundamental frequency at a power level 6 dB lower than the fundamental frequency.

45. An apparatus as in claim 35, wherein the array transducer transmits the ultrasonic energy at a sufficient power to generate a second harmonic in the tissue having a maximum power level of less than 15 dB from the maximum power level of the fundamental frequency in the tissue.

46. An apparatus as in claim 35, wherein the array transducer has a checkerboard pattern formed by a plurality of elements, each element used for either transmit or receive.

47. An apparatus as in claim 35, wherein the array transducer has a checkerboard pattern formed by a total number of elements, at least 25% of the total number of elements being used to transmit and a plurality of the elements used to receive.

48. An apparatus as in claim 35, wherein the array transducer has a checkerboard pattern formed by a total number of elements, at least 25% of the total number of elements connected to high-voltage electronics to transmit the ultrasonic energy, and a plurality of the elements connected to low-voltage electronics to receive the generated harmonic.

49. An apparatus as in claim 35, wherein the array transducer is formed by a plurality of elements in an alternating transmit-receive checkerboard pattern.

50. An apparatus as in claim 35, further comprising:
a low-voltage circuit; and
a high-voltage circuit driving the array transducer to transmit the ultrasonic energy, the high voltage circuit including a high-voltage FET, the low-voltage circuit and the high-voltage circuit being monolithically formed on a single substrate and being housed in the handle.

51. An apparatus as in claim 35, further comprising:
a low-voltage circuit; and
a high-voltage circuit driving the array transducer to transmit the ultrasonic energy, the low-voltage circuit and the high-voltage circuit being formed on a single substrate and being housed in the handle.

52. An apparatus as in claim 35, further comprising:
means for providing a low-voltage circuit and a high-voltage circuit both formed on the same single substrate, the high-voltage circuit for driving the array transducer to transmit the ultrasonic energy, said means being housed in the handle.

53. An apparatus as in claim 35, further comprising:
a communication channel connecting the handle to the ultrasound processing equipment to allow the control signals produced by the electronic processing equipment to be provided to the beamforming electronics in the handle.

54. An apparatus as in claim 53, wherein the communication channel is one of the group consisting of a cable and a wireless communications channel.

55. An apparatus comprising:
electronic processing equipment producing control signals for ultrasound imaging;
a handle external to the electronic processing equipment and positionable near tissue;
at least some transmit beamforming electronics housed in the handle;
a communication channel connecting the electronic processing equipment to the transmit beamforming electronics in the handle so that the transmit beamforming electronics generates excitation signals in accordance with the control signals produced by the electronic processing equipment; and
a two-dimensional (2D) array transducer housed in the handle and, in accordance with the excitation signals, transmitting ultrasonic energy in tissue near which the handle is positioned at a fundamental frequency and of sufficient power to generate a harmonic of the fundamental frequency in the tissue.

56. An apparatus as in claims 55, wherein the array transducer receives the generated harmonic, the apparatus further comprising:
at least some receive beamforming electronics housed in the handle and processing the received harmonic, the receive beamforming electronics connected to the electronic processing equipment by the communication channel to allow the electronic processing equipment to display an ultrasonic image on a display in accordance with the harmonic processed by the receive beamforming electronics.

57. An apparatus as in claim 55, wherein the array transducer includes a total number of elements of which at least 25% are excited to transmit the ultrasonic energy.

58. An apparatus as in claim 55, further comprising:
a high voltage circuit driving the array transducer to transmit the ultrasonic energy and housed in the handle.

59. An apparatus as in claim 55, further comprising:
a high voltage field effect transistor (FET) driving the array transducer to transmit the ultrasonic energy and housed in the handle.

60. An apparatus as in claim 55, further comprising:
means for driving the array transducer with a high voltage to transmit the ultrasonic energy, said means being housed in the handle.

61. An apparatus as in claim 55, wherein the array transducer includes a plurality of piezoelectric elements forming the array transducer, the apparatus further comprising:
a high impedance backing for the piezoelectric elements and housed in the handle.

62. An apparatus as in claim 55, wherein the array transducer includes a plurality of piezoelectric elements forming the array transducer, the apparatus further comprising:
means for providing a high impedance backing for the piezoelectric elements, said means being housed in the handle.

63. An apparatus as in claim 55, wherein the array transducer is constructed of materials comprising a single crystal.

64. An apparatus as in claim 55, wherein the array transducer is constructed of a plurality of piezoelectric elements of a single crystal.

65. An apparatus as in claim 55, wherein the array transducer transmits the ultrasound energy with a waveform having a bandwidth BW greater than or equal to 60% of the fundamental frequency, where BW=(f_{B}-f_{A}), f_{B} is a higher frequency than the fundamental frequency at a power level 6 dB lower than at the fundamental frequency, f_{A} is a lower frequency than the fundamental frequency at a power level 6 dB lower than the fundamental frequency.

66. An apparatus as in claim 55, wherein the array transducer transmits the ultrasonic energy at a sufficient power to generate a second harmonic in the tissue having a maximum power level of less than 15 dB from the maximum power level of the fundamental frequency in the tissue.

67. An apparatus as in claim 55, wherein the array transducer has a checkerboard pattern formed by a plurality of elements, each element used for either transmit or receive.

68. An apparatus as in claim 55, wherein the array transducer has a checkerboard pattern formed by a total number of elements, at least 25% of the total number of elements being used to transmit and a plurality of the elements used to receive.

69. An apparatus as in claim 55, wherein the array transducer has a checkerboard pattern formed by a total number of elements, at least 25% of the total number of elements connected to high-voltage electronics in the handle to transmit the ultrasonic energy, and a plurality of the elements connected to low-voltage electronics in the handle to receive the generated harmonic.

70. An apparatus as in claim 55, wherein the array transducer is formed by a plurality of elements in an alternating transmit-receive checkerboard pattern.

71. An apparatus as in claim 55, further comprising:
a low-voltage circuit; and
a high-voltage circuit driving the array transducer to transmit the ultrasonic energy, the high voltage circuit including a high-voltage FET, the low-voltage circuit and the high-voltage circuit being monolithically formed on a single substrate and being housed in the handle.

72. An apparatus as in claim 55, further comprising:
a low-voltage circuit; and
a high-voltage circuit driving the array transducer to transmit the ultrasonic energy, the low-voltage circuit and the high-voltage circuit being formed on a single substrate and being housed in the handle.

73. An apparatus as in claim 55, further comprising:
means for providing a low-voltage circuit and a high-voltage circuit both formed on the same single substrate, the high-voltage circuit for driving the array transducer to transmit the ultrasonic energy, said means being housed in the handle.

74. An apparatus as in claim 55, wherein the communication channel is one of the group consisting of a cable and a wireless communications channel.

75. An apparatus comprising:
an array transducer having a checkerboard pattern formed by a plurality of elements, each element used to either transmit ultrasonic energy at a fundamental frequency or receive a signal generated in tissue by the transmitted ultrasonic energy.

76. An apparatus comprising:
an array transducer having a checkerboard pattern formed by a total number of elements, at least 25% of the total number of elements used to transmit ultrasonic energy at a fundamental frequency, and a plurality of the elements used to receive a signal generated in tissue by the transmitted ultrasonic energy.

77. An apparatus comprising:
an array transducer having a checkerboard pattern formed by a total number of elements, at least 25% of the total number of elements connected to high-voltage electronics to transmit ultrasonic energy at a fundamental frequency, and a plurality of the elements connected to low-voltage electronics to receive a signal generated in tissue by the transmitted ultrasonic energy.

78. An apparatus comprising:
an array transducer having a checkerboard pattern formed by a plurality of elements in an alternating transmit-receive checkerboard pattern, where transmitting elements transmit ultrasonic energy at a fundamental frequency and receiving elements receive a signal generated in tissue by the transmitted ultrasonic energy.
